(19) United States
(12) Patent Application Publication
(10) Pub. No.: US 2024/0145333 A1
(43) Pub. Date: May 2, 2024

(54) Liquid cooling device for memory module

(71) Applicant: Celestica Technology Consultancy (Shanghai) Co. Ltd, Shanghai (CN)

(72) Inventors: Mingqing LUO, Shanghai (CN); Yaoyin FAN, Shanghai (CN); Chengzhi LIU, Shanghai (CN); Kai CHEN, Shanghai (CN)

(73) Assignee: Celestica Technology Consultancy (Shanghai) Co. Ltd, Shanghai (CN)

(21) Appl. No.: 18/337,399

(22) Filed: Jun. 19, 2023

(30) Foreign Application Priority Data
Jun. 21, 2022 (CN) 2022107070118
Jun. 21, 2022 (CN) 2022215640087

(51) Int. Cl. H01L 23/367; H01L 23/40; H01L 23/473

(52) U.S. Cl. CPC H01L 23/3672; H01L 23/40; H01L 23/473; H01L 2023/4087

(57) ABSTRACT

A liquid cooling device for cooling a memory module is provided. The liquid cooling device includes a slot, installed on a motherboard, where the memory module is inserted into the slot; a first heat sink and a second heat sink, where the first, second heat sinks dissipate heat from the memory module between the first heat sink and the second heat sink, with the first, second heat sinks abutting the memory module; a liquid cooling plate, movably installed on a side of the slot, covering a top part of the memory module after the memory module is inserted into the slot, for liquid cooling of the first heat sink and the second heat sink; and at least one first fixing clamp, abutting surfaces of the first, second heat sinks, and clamping the first, second heat sinks and the memory module together.

### CROSS REFERENCE TO RELATED APPLICATION

The present application claims the benefit of priority to Chinese Patent Application No. CN 202210707011.8, entitled “Liquid Cooling Device for Cooling Memory Module”, filed with CNIPA on Jun. 21, 2022, the disclosure of which is incorporated herein by reference in its entirety, and the present application also claims the benefit of priority to Chinese Patent Application No. CN 202221564008.7, entitled “Liquid Cooling Device for Cooling Memory Module”, filed with CNIPA on Jun. 21, 2022, the disclosure of which is incorporated herein by reference in its entirety.

### FIELD OF TECHNOLOGY

The present disclosure relates to the field of cooling technology for electronic devices, and more specifically, to the field of liquid cooling technology.

### BACKGROUND

Due to high power consumption, low maximum permissible temperature, compact structure, and difficulty in using large heat sinks for heat dissipation, it has become a major challenge to effectively dissipate heat from memory modules in servers. It is difficult to meet heat dissipation needs of the memory modules in high-power servers using traditional air cooling. Liquid cooling, as a highly efficient heat dissipation method, can better solve the problem of effectively dissipating heat from the memory modules.

To solve the problem of high tolerance requirements for liquid cooling design due to the compact structure of the memory modules, a common structure of a liquid cooling device is provided, as shown in FIG. 1, where a liquid cooling channel is arranged between two adjacent memory modules, and the liquid cooling channel is provided with liquid cooling components each including a liquid cooling tube 15, a heat sink 12 and a thermal pad 13. After the liquid cooling components are connected in parallel, they are fixed in a chassis. Each of the memory modules 11 is inserted into a corresponding slot 14 through a gap between two adjacent liquid cooling components. In the liquid cooling device, chips of the memory modules 11 can be directly cooled, with high heat dissipation efficiency. However, this requires precise assembly and the integrated design of the liquid cooling channels demands high tolerance. This makes the overall design and installation process more challenging.

Another liquid cooling device is shown in FIGS. 2-3, where liquid cooling channels are provided at a bottom part of the memory modules 21, and two heat sinks 24, two layers of first thermal pads 22, and one of the memory module 21 are fixed on a corresponding slot 26 by a clamp 27 to form a heat dissipation module, so that the memory modules 21 are in reliable and good contact with the heat sinks 24. The heat sinks 24 and liquid cooling tubes 23 are two separate parts in FIGS. 2-3. In order to ensure good heat conduction in the process of heat conduction from the heat sinks 24 to the liquid cooling tubes 23 through second thermal pads 25, it is necessary to increase the contact area between the heat sinks 24 and the liquid cooling tubes 23. As shown in FIGS. 2-3, heat conduction keys 28 distributed in a staggered manner are arranged below the heat sinks 24. The heat conduction keys 28 distributed in the staggered manner can ensure that each two adjacent memory modules 21 are both in reliable and good contact with corresponding liquid cooling tubes 23, without affecting the plugging and unplugging of the memory modules 21. However, there are still some technical problems in the liquid cooling device in FIGS. 2-3, such as high overall assembly requirements, high tolerance requirements, and the difficulty in overall design and installation.

In addition, the liquid cooling devices shown in FIGS. 1-3 adopt integral assembly, where the liquid cooling channel of the memory modules is connected to a main liquid cooling channel. To replace chips or perform other installation and maintenance tasks, the entire liquid cooling devices must be disassembled using professional fixtures, resulting in maintenance difficulty of the liquid cooling devices.

Therefore, high tolerance requirements for liquid cooling design due to the compact structure of memory modules is an urgent problem to be solved by those skilled in the art.

### SUMMARY

The present disclosure provides a liquid cooling device for cooling a memory module, for solving the technical problems in traditional liquid cooling devices, such as, high tolerance requirements due to the compact structure of memory modules and inconvenience of performing liquid cooling maintenance.

The liquid cooling device includes a slot, installed on a motherboard, wherein the memory module is inserted into the slot; a first heat sink and a second heat sink, wherein the first heat sink and the second heat sink dissipate heat from the memory module between the first heat sink and the second heat sink, with the first heat sink and the second heat sink abutting the memory module; a liquid cooling plate, movably installed on a side of the slot, covering a top part of the memory module after the memory module is inserted into the slot, for liquid cooling of the first heat sink and the second heat sink; and at least one first fixing clamp, abutting surfaces of the first heat sink and the second heat sink, and clamping the first heat sink, the second heat sink and the memory module together.

In an embodiment of the present disclosure, the liquid cooling plate is connected to a vertical support plate through a rotating shaft, and the liquid cooling plate is configured to cover the top part of the memory module or rotate away from the top part of the memory module when the liquid cooling plate rotates around the rotating shaft.

In an embodiment of the present disclosure, a side of the liquid cooling plate close to the rotating shaft is provided with a coolant inlet and a coolant outlet.

In an embodiment of the present disclosure, an interior of the liquid cooling plate is provided with a plurality of flow channels with preset shapes.

In an embodiment of the present disclosure, a first thermal pad is provided between the first heat sink and the memory module, and between the second heat sink and the memory module.

In an embodiment of the present disclosure, longitudinal cross-sections of the first heat sink and the second heat sink are T-shaped, so that a lower surface of a top part of the first heat sink and a lower surface of a top part of the second heat sink abut the top part of the memory module.

In an embodiment of the present disclosure, a second thermal pad is provided between the liquid cooling plate and a top part of the first heat sink, and between the liquid cooling plate and a top part of the second heat sink.

In an embodiment of the present disclosure, further including at least one second fixing clamp, wherein the at least one second fixing clamp is tightly pressed against an upper surface of the liquid cooling plate, two ends of each of the at least one second fixing clamp are fixed on the motherboard, and the at least one second fixing clamp is configured to tightly press the liquid cooling plate against a top part of the first heat sink and a top part of the second heat sink.

In an embodiment of the present disclosure, each of the at least one second fixing clamp includes: a first fixing rod, fixed on the motherboard and located on a first side of the liquid cooling plate; a second fixing rod, fixed on the motherboard and located on a second side of the liquid cooling plate; and a pressing part, connected between the first fixing rod and the second fixing rod, and tightly pressed against the upper surface of the liquid cooling plate.

In an embodiment of the present disclosure, the pressing part is Z-shaped.

As described above, the liquid cooling device for cooling the memory module of the present disclosure has the following beneficial effects:

The present disclosure effectively addresses troublesome plugging and unplugging between the memory module and the liquid cooling device in the related art. Considering the compact structure of the memory module, the liquid cooling plate is provided at the top part of the memory module for heat dissipation, making it more practical and user-friendly. This reduces the overall manufacturing and installation tolerance requirements. Additionally, one end of the liquid cooling plate features a rotating shaft, allowing it to be rotated by the rotating shaft, and fixed in with a buckle. This makes it easier to disassemble and maintain the memory module, improving the liquid cooling device's maintainability and ease of installation.

### BRIEF DESCRIPTION OF THE DRAWINGS

FIG. 1 is a schematic structural diagram of a liquid cooling device in the prior art.

FIGS. 2 and 3 are schematic structural diagrams of another liquid cooling device in the prior art.

FIG. 4 is a schematic diagram of an overall structure of a liquid cooling device for cooling a memory module according to an embodiment of the present disclosure;

FIG. 5 is a schematic structural diagram of a liquid cooling device for cooling a memory module with a single slot according to an embodiment of the present disclosure;

FIG. 6 is a front view of a liquid cooling device for cooling a memory module with a single slot according to an embodiment of the present disclosure;

FIG. 7 is a schematic structural diagram of a liquid cooling plate of a liquid cooling device for cooling a memory module according to an embodiment of the present disclosure;

FIG. 8 is a front view of a liquid cooling device for cooling a memory module with multiple slots according to an embodiment of the present disclosure.

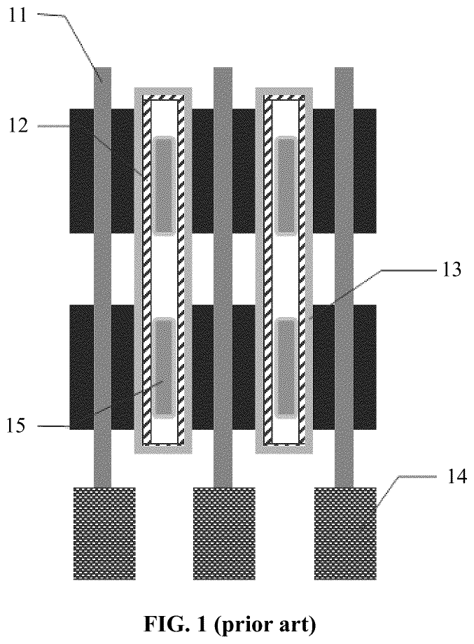

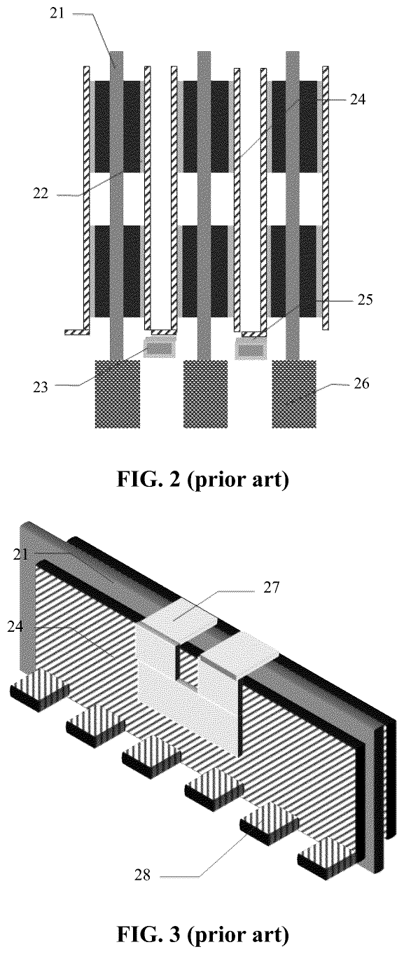

### REFERENCE NUMERALS

11 Memory module
12 Heat sink
13 Thermal pad
14 Slot
15 Liquid cooling tube
21 Memory module
22 First thermal pad
23 Liquid cooling tube
24 Heat sink
25 Second thermal pad
26 Slot
27 Clamp
28 Heat conduction key
100 Liquid cooling device
110 Slot
120 Memory module
130 Heat sink
140 Liquid cooling plate
141 Coolant inlet
142 Coolant outlet
150 First fixing clamp
160 Second fixing clamp
161 First fixing rod
162 Second fixing rod
163 Pressing part
170 Vertical support plate
180 Rotating shaft
190 First thermal pad
1100 Second thermal pad
200 Motherboard

### DETAILED DESCRIPTION

The implementations of the present disclosure are described below through specific examples. Those skilled in the art can easily understand the other advantages and effects of the present disclosure from the content disclosed in this specification.

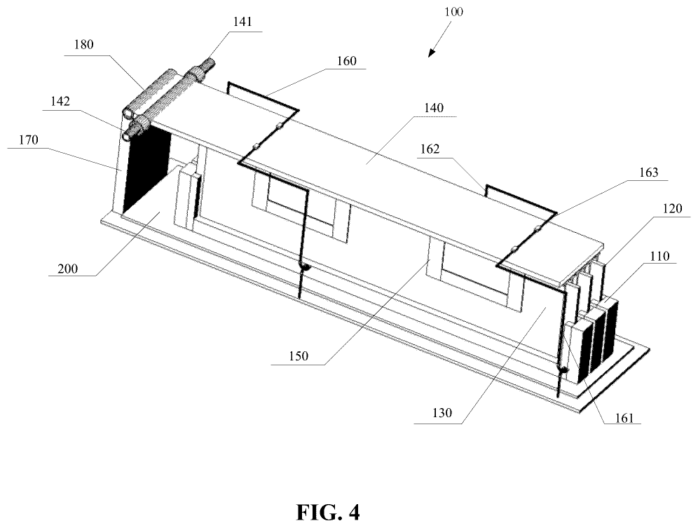

Please refer to FIGS. 4-8. It should be noted that the structure, proportion, size, etc. illustrated in the drawings of this specification are only used to match the contents disclosed in the specification for the understanding and reading of those skilled in the art, and are not used to limit the conditions under which the present disclosure can be implemented. Any modification of the structure, change of proportion or adjustment of the size, without affecting the efficacy of the present disclosure and the purpose it can achieve, should still fall within the scope of the technical contents disclosed in the present disclosure. At the same time, the terms such as “up”, “down”, “left”, “right”, “middle” and “one” used in this specification are only for the clarity of the description, and are not intended to limit the scope of the present disclosure, and any change or adjustment of relative relationships thereof without substantial change of the technical content herein shall still fall within the scope of the present disclosure.

The present disclosure provides a liquid cooling device for cooling a memory module, for solving technical problems in traditional liquid cooling devices, such as, high tolerance requirements due to the compact structure of the memory module and inconvenience of performing liquid cooling maintenance.

The principle and implementation of the liquid cooling device for cooling the memory module according to some embodiments of the present disclosure will be described in detail below, so that those skilled in the art can understand the liquid cooling device for cooling the memory module of the present disclosure without creative labor.

As shown in FIGS. 4-8, the liquid cooling device 100 includes at least one slot 110, at least two heat sinks 130, a liquid cooling plate 140, at least one first fixing clamp 150, and at least one second fixing clamp 160.

The liquid cooling device 100 for cooling the memory module 120 according to an embodiment will be described in detail below.

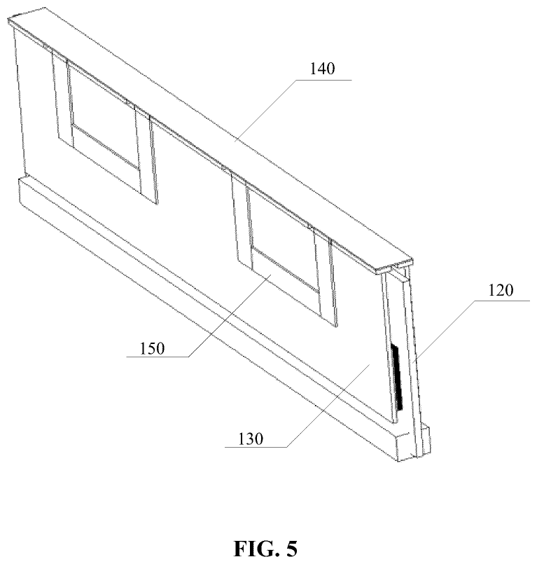

In an embodiment, there are one or more slots 110. FIG. 4 and FIG. 8 are schematic structural diagrams of the liquid cooling device 100 for cooling the memory module 120 with multiple slots 110 according to some embodiments of the present disclosure. FIG. 5 is a schematic structural diagram of the liquid cooling device 100 for cooling the memory module 120 with a single slot according to an embodiment of the present disclosure. In an embodiment, the at least one slot 110 is installed on a motherboard 200, and is for inserting the memory module 120 in FIG. 5. When there are multiple slots 110, the multiple slots 110 are arranged side by side, and one memory module 120 is inserted into a corresponding slot 110 through a gap of the liquid cooling device 100.

In an embodiment, the memory module 120 may be, such as, a dual-inline-memory-module (DIMM), or other types of storage modules, such as, a pluggable hard disk. The memory module 120 typically has chips whose surfaces need to be cooled e, or the memory module 120 is a to-be-cooled device with a relatively flat package surface. Moreover, the memory module 120 can be inserted into a corresponding slot 110.

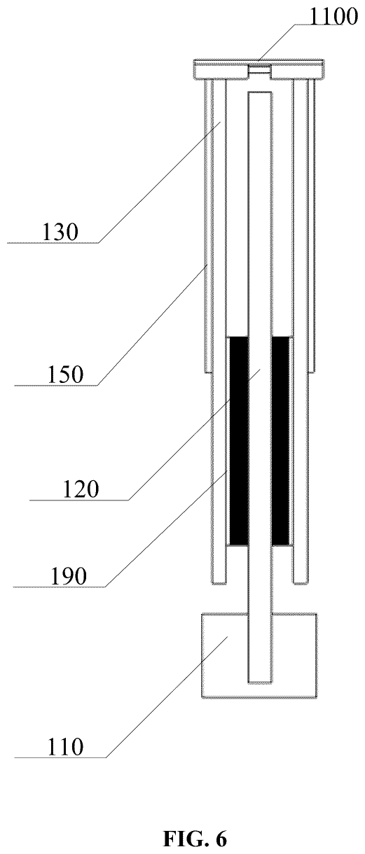

In an embodiment, the liquid cooling device 100 for cooling the memory module 120 includes two heat sinks 130 (e.g., a first heat sink and a second heat sink shown in FIGS. 5-6). The first heat sink and the second heat sink dissipate heat from the memory module 120 between the first heat sink and the second heat sink, with the first heat sink and the second heat sink abutting the memory module 120. The first heat sink and the second heat sink are configured to dissipate heat from the memory module 120 between the first heat sink and the second heat sink. In other words, the first heat sink dissipates heat from a first surface of the memory module 120 facing the first heat sink, and the second heat sink dissipates heat from a second surface of the memory module 120 facing the second heat sink, wherein the first surface of the memory module 120 is opposite to the second surface of the memory module 120. When the memory module 120 is inserted into the slot 110, the first surface of the memory module 120 abuts a surface of the first heat sink, and the second surface of the memory module 120 abuts a surface of the second heat sink, thereby dissipating heat from the memory module 120 through the first heat sink and the second heat sink.

In an embodiment, as shown in FIGS. 5-6, longitudinal cross-sections of the heat sinks 130 are T-shaped, so that lower surfaces of top parts of the heat sinks abut the top part of the memory module 120.

The heat generated by the chips in the memory module 120 is conducted to the top parts of the heat sinks 130 through the T-shaped heat sinks 130, and then the heat conducted to the top parts of the heat sinks 130 is further taken away by configuring a liquid cooling plate 140 on the top parts of the heat sinks 130, thereby effectively improving the cooling efficiency.

In an embodiment, as shown in FIGS. 4-6, the liquid cooling device 100 for cooling the memory module 120 includes at least one first fixing clamp 150, abutting surfaces of the heat sinks 130, and clamping the heat sinks 130 and the memory module 120 together.

In an embodiment, the number of the at least one first fixing clamp 150 is one or more. For example, as shown in FIGS. 4-6, there are two first fixing clamps 150, the two first fixing clamps 150 are evenly arranged along the top parts of the heat sinks 130 and the memory module 120, and the two first fixing clamps 150 also abuts the surfaces of the heat sinks 130.

In an embodiment, the at least one first fixing clamp 150 includes a first clamping part, a second clamping part, and a connecting part. The first clamping part tightly abuts a surface of the first heat sink away from the first surface of the memory module 120, and the second clamping part tightly abuts a surface of the second heat sink away from the second surface of the memory module 120. The connecting part connects the first clamping part and the second clamping part, and extends over or abuts the top parts of the heat sinks 130.

The first clamping part and the second clamping part are plate-shaped or have hollow structures.

Considering the compact structure of the memory module 120, the above embodiments use the at least one first fixing clamp 150 to clamp the heat sinks 130, and the memory module 120 together, reducing installation tolerance requirements.

Therefore, the liquid cooling device 100 of the above embodiments can effectively solve the problem in the related art, such as, high tolerance requirements for liquid cooling design due to the compact structure of the memory module 120.

It should be noted that, in an embodiment, a first thermal pad 190 is provided between the heat sinks 130 and the memory module 120, to improve heat dissipation performance. That is, the chips that need to be cooled of the memory module 120 are in contact with the heat sinks 130 through the at least one first fixing clamps 150, and the first thermal pad 190 is inserted between the heat sinks 130 and the memory module 120.

The first thermal pad 190 is made of a thermal interface material. When the memory module 120 is inserted into the slot 110, the first thermal pad 190 directly abuts the first, second surfaces of the memory module 120, conducting the heat generated by the memory module 120 to the heat sinks 130.

In an embodiment, the length of the heat sinks 130 and the length of the first thermal pad 190 may be equal or unequal. When the length of the heat sinks 130 and the length of the first thermal pad 190 are not equal, the length of the first thermal pad 190 matches the length of the first, second surfaces of the memory module 120.

In an embodiment, the liquid cooling plate 140 is movably installed on a side of the slot 110. After the memory module 120 is inserted into the slot 110, the liquid cooling plate 140 can then rotate and cover the top part of the memory module 120 for liquid cooling of the heat sinks 130.

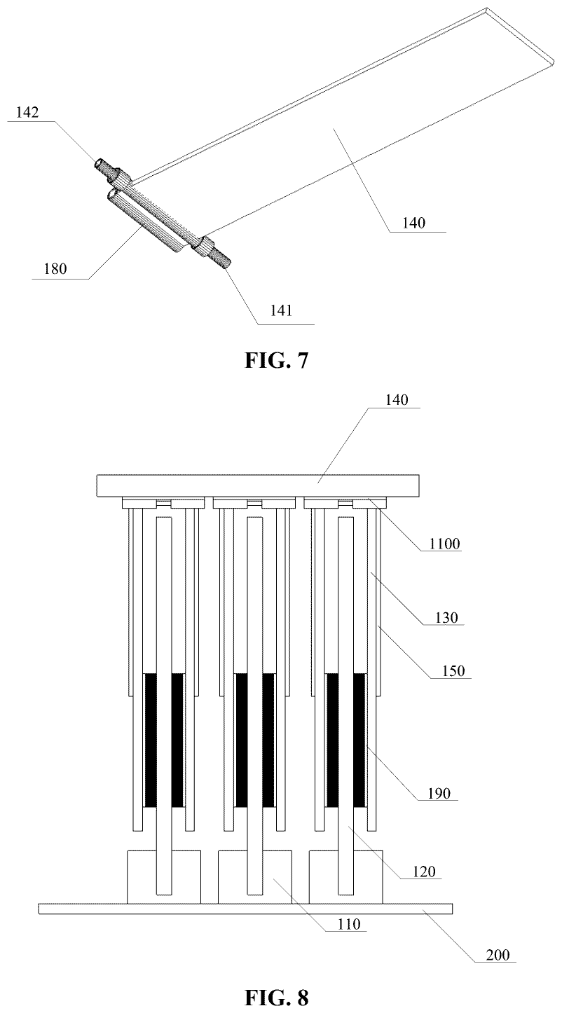

In an embodiment, as shown in FIGS. 4 and 7, the liquid cooling plate 140 is connected to a vertical support plate 170 through a rotating shaft 180, and the liquid cooling plate 140 is configured to cover the top part of the memory module 120 or rotate away from the top part of the memory module 120 when the liquid cooling plate 140 rotates around the rotating shaft 180.

An end of the liquid cooling plate 140 is provided with the rotating shaft 180, and the liquid cooling plate 140 can rotate around the rotating shaft 180. By rotating the liquid cooling plate 140, any memory module 120 can be easily removed for maintenance, thereby facilitating assembly and maintenance.

In an embodiment, as shown in FIGS. 4 and 7, a side of the liquid cooling plate 140 close to the rotating shaft 180 is provided with a coolant inlet 141 and a coolant outlet 142; an interior of the liquid cooling plate 140 is provided with a plurality of flow channels with preset shapes.

In an embodiment, the liquid cooling plate 140 includes the coolant inlet 141 and the coolant outlet 142, and the interior of the liquid cooling plate 140 is provided with liquid flow channels for an external cooling medium to enter the liquid cooling plate 140 and flow, thereby taking away the heat generated by the chips of the memory module 120.

In an embodiment, a second thermal pad 1100 is also provided between the liquid cooling plate 140 and the top parts of the heat sinks 130, to improve heat dissipation performance.

The second thermal pad 1100 is made of a thermal interface material. When the liquid cooling plate 140 covers the top parts of the heat sinks 130, the first thermal pad 190 directly abuts a surface of the liquid cooling plate 140, thereby conducting the heat of the heat sinks 130 to the liquid cooling plate 140.

In an embodiment, the number of the at least one second fixing clamp 160 is one or more. For example, as shown in FIG. 4, there are two second fixing clamps 160, which are evenly arranged along a length direction of the liquid cooling plate 140.

In an embodiment, the at least one second fixing clamp 160 is tightly pressed against an upper surface of the liquid cooling plate 140, two ends of each of the at least one second fixing clamp 160 are fixed on the motherboard 200, and the at least one second fixing clamp 160 is configured to tightly press the liquid cooling plate 140 against the top parts of the heat sinks.

In an embodiment, each of the at least one second fixing clamp 160 includes a first fixing rod 161, a second fixing rod 162, and a pressing part 163. The first fixing rod 161 is fixed on the motherboard 200 and located on a first side of the liquid cooling plate 140; the second fixing rod 162 is fixed on the motherboard 200 and located on a second side of the liquid cooling plate 140; the pressing part 163 is connected between the first fixing rod 161 and the second fixing rod 162 and tightly pressed against the upper surface of the liquid cooling plate 140.

In an embodiment, the pressing part 163 is Z-shaped. That is, the liquid cooling plate 140 is tightly pressed against the top parts of the heat sinks 130 by using two or more Z-shaped pressing parts 163.

In an embodiment, the liquid cooling channel is provided on the top part of the memory module 120, and is fixed by two (or more) Z-shaped pressing parts 163 to improve the liquid cooling effect. Moreover, a single memory module 120 can be easily removed for maintenance by loosening the Z-shaped pressing part 163 and rotating the liquid cooling plate 140 during maintenance, thereby effectively reducing difficulty in maintaining the memory modules 120.

The working principle of the liquid cooling device 100 for cooling the memory module of the present disclosure is as follows:

The heat sinks and the chips of the memory module 120 are clamped together by the at least one first fixing clamp 150, and the heat generated by the chips of the memory module 120 is conducted to the top parts of the heat sinks. The liquid cooling plate 140 is provided at the top parts of the heat sinks. The liquid cooling plate 140 has the liquid cooling medium flowing inside. The heat generated by the chips of the memory module 120 is taken away by the liquid cooling plate 140. The liquid cooling plate 140 is fixed using Z-shaped pressing parts 163 for easy fixing and removal; an end of the liquid cooling plate 140 is provided with the rotating shaft 180, and the liquid cooling plate 140 can rotate around the rotating shaft 180. The liquid cooling plate 140 is configured to be rotatable to avoid troublesome plugging and unplugging between the memory module 120 and the liquid cooling device 100, and also facilitates assembly and maintenance.

In summary, the present disclosure effectively addresses troublesome plugging and unplugging between the memory module and the liquid cooling device in the related art. Considering the compact structure of the memory module, the liquid cooling plate is provided at the top part of the memory module for heat dissipation, making it more practical and user-friendly. This reduces the overall manufacturing and installation tolerance requirements. Additionally, one end of the liquid cooling plate features a rotating shaft, allowing it to be rotated by the rotating shaft, and fixed in with a buckle. This makes it easier to disassemble and maintain the memory module, improving the liquid cooling device's maintainability and ease of installation. The present disclosure effectively overcomes various shortcomings and has high industrial value.

The above embodiments are illustrative of the principles and benefits of the disclosure rather than restrictive of the scope of the disclosure. Persons skilled in the art can make modifications and changes to the embodiments without departing from the spirit and scope of the disclosure. Therefore, all equivalent modifications and changes made by persons skilled in the art without departing from the spirit and technical concepts disclosed in the disclosure shall still be deemed falling within the scope of the claims of the disclosure.

What is claimed is:

1. A liquid cooling device for cooling a memory module, comprising:
a slot, installed on a motherboard, wherein the memory module is inserted into the slot;
a first heat sink and a second heat sink, wherein the first heat sink and the second heat sink dissipate heat from the memory module between the first heat sink and the second heat sink, with the first heat sink and the second heat sink abutting the memory module;
a liquid cooling plate, movably installed on a side of the slot, covering a top part of the memory module after the memory module is inserted into the slot, for liquid cooling of the first heat sink and the second heat sink; and
at least one first fixing clamp, abutting surfaces of the first heat sink and the second heat sink, and clamping the first heat sink, the second heat sink and the memory module together.

2. The liquid cooling device for cooling the memory module according to claim 1, wherein the liquid cooling plate is connected to a vertical support plate through a rotating shaft, and the liquid cooling plate is configured to cover the top part of the memory module or rotate away from the top part of the memory module when the liquid cooling plate rotates around the rotating shaft.

3. The liquid cooling device for cooling the memory module according to claim 2, wherein a side of the liquid cooling plate close to the rotating shaft is provided with a coolant inlet and a coolant outlet.

4. The liquid cooling device for cooling the memory module according to claim 2, wherein an interior of the liquid cooling plate is provided with a plurality of flow channels with preset shapes.

5. The liquid cooling device for cooling the memory module according to claim 1, wherein a first thermal pad is provided between the first heat sink and the memory module, and between the second heat sink and the memory module.

6. The liquid cooling device for cooling the memory module according to claim 1, wherein longitudinal cross-sections of the first heat sink and the second heat sink are T-shaped, so that a lower surface of a top part of the first heat sink and a lower surface of a top part of the second heat sink abut the top part of the memory module.

7. The liquid cooling device for cooling the memory module according to claim 1, wherein a second thermal pad is provided between the liquid cooling plate and a top part of the first heat sink, and between the liquid cooling plate and a top part of the second heat sink.

8. The liquid cooling device for cooling the memory module according to claim 1, further comprising at least one second fixing clamp, wherein the at least one second fixing clamp is tightly pressed against an upper surface of the liquid cooling plate, two ends of each of the at least one second fixing clamp are fixed on the motherboard, and the at least one second fixing clamp is configured to tightly press the liquid cooling plate against a top part of the first heat sink and a top part of the second heat sink.

9. The liquid cooling device for cooling the memory module according to claim 8, wherein each of the at least one second fixing clamp comprises:
a first fixing rod, fixed on the motherboard and located on a first side of the liquid cooling plate;
a second fixing rod, fixed on the motherboard and located on a second side of the liquid cooling plate; and
a pressing part, connected between the first fixing rod and the second fixing rod, and tightly pressed against the upper surface of the liquid cooling plate.

10. The liquid cooling device for cooling the memory module according to claim 9, wherein the pressing part is Z-shaped.
